(19) United States
(12) Patent Application Publication
(10) Pub. No.: US 2009/0121244 A1
(43) Pub. Date: May 14, 2009

(54) LED packaging structure and production method thereof

(76) Inventor: Steven Lo, Jhubei City (TW)

Correspondence Address: HDLS Patent & Trademark Services, P.O. BOX 220746, CHANTILLY, VA, 20153-0746, US

(21) Appl. No.: 11/936,824

(22) Filed: Nov. 8, 2007

(51) Int. Cl. H01L 33/00; H01L 21/00

(52) U.S. Cl. 257/98; 438/26; 257/E33.058

(57) ABSTRACT

An LED packaging structure and a production method thereof; the LED packaging structure includes an LED die placed on a metal substrate and packed with seal in conjunction with a transparent substrate to deliver advantages of compact, simplified process and long service life and provide significant advancement and industrial value when compared to the prior art.

### BACKGROUND OF THE INVENTION

(a) Field of the Invention

The present invention is related to an LED packaging structure and a production method thereof, and more particularly to a new technology of having a transparent substrate as one of LED packaging materials.

(b) Description of the Prior Art

A light-emitting diode (LED) having been comprehensively applied in various types of electronic products is related to a solid-state conductor device. It working principle involves two carriers separated from each other in the diode (i.e., electrons carrying negative electricity and electric holes carrying positive electricity) and direct conversion of electric energy into optical energy to produce optical energy when those electrons and electric holes are incorporated to each other as conducted through with a current by applying voltage to both ends of a positive electrode and a negative electrode disposed in a semiconductor. In a conventional LED packaging process including but not limited to Die Bond, Wire Bond, and Molding, wherein a LED die is bonded to a reflection cup or an SMD base of a circuit board with transparent glue or silver epoxy before being processed with connection between both positive and negative electrodes to the lead frame using a gold wire or aluminum wire bonder, and finally the LED is packed up with epoxy. Further improvement and breakthrough are justified to lead in the market in coping with further advancement and upgrading product competition strength even though those manufacturing processes of the prior art are not found with any major flaws. Therefore, the present invention discloses an innovative LED packaging structure and a manufacturing process thereof to improve the existing process, particularly, to simplify the process for further upgrading and advancing the perfection production technology of LED packaging.

### SUMMARY OF THE INVENTION

The primary purpose of the present invention is to provide an LED packaging structure and a production method thereof is to place the LED die on a metal substrate in conjunction with a transparent substrate and packed with seal to achieve a simplified manufacturing process by giving up existing processes of Wire Bond and Molding so to increase production capacity, lower production cost, and help mass production by lot. Furthermore, as carrying out the packaging for multiple units, circuitry can be produced on the transparent substrate without using a circuit board; size and area of the structure of the present invention are smaller than the conventional structure to provide an application range meeting all requirements; packaging with the seal yields excellent waterproof and dustproof properties and allowing vacuum packaging or inert gas filling to extend service life; and permitting larger area of bonding of multiple units before breaking to meet mass production by lot.

Another major niche provided by the LED packaging structure of the present invention rests in that manufacturers do not have to purchase new facilities and are able to carry out most of the process of the present invention with the exiting TFT LCD manufacturing facilities thus to significantly reduce development costs of facilities, fast introduction into production for time efficiency, and to catch from behind in case of a manufacturer with manufacturing technology falling behind or to expand leading edge in case of a manufacturer already leading in the manufacturing technology.

Another innovation and only first seen in this art about the present invention is that LED light emitting characteristics can be changed simply by having either side of the transparent substrate coated with a thin film or covered up with a fluorescent material.

### BRIEF DESCRIPTION OF THE DRAWINGS

FIG. 1 is a perspective view of a first preferred embodiment of the present invention.

FIG. 2 is an exploded view of the first preferred embodiment of the present invention.

FIG. 3 is a sectional view of the first preferred embodiment of the present invention.

FIG. 4 is a magnified view showing a local part of the first preferred embodiment of the preset invention.

FIG. 5 is a perspective view of a second preferred embodiment of the present invention.

FIG. 6 is an exploded view of the second preferred embodiment of the present invention.

FIG. 7 is a sectional view of the second preferred embodiment of the present invention.

FIG. 8 is a schematic view showing that the present invention is applied in RGB multi-chip package.

FIG. 9 is a perspective view showing the present invention is combined with multiple connection elements and a heat sink.

FIG. 10 is an exploded view showing that the present invention is combined with multiple connection elements and the heat sink.

FIG. 11 is a sectional view showing that the present invention is combined with multiple connection elements and a heat sink.

FIG. 12 is a schematic view showing that the present invention is applied in an LED light bar.

FIG. 13 is an equivalent circuit diagram showing wiring for connection among multiple LEDs of the application illustrated in FIG. 12.

FIG. 14 is a schematic view showing that the present invention is applied in a local area package.

### DETAILED DESCRIPTION OF THE PREFERRED EMBODIMENTS

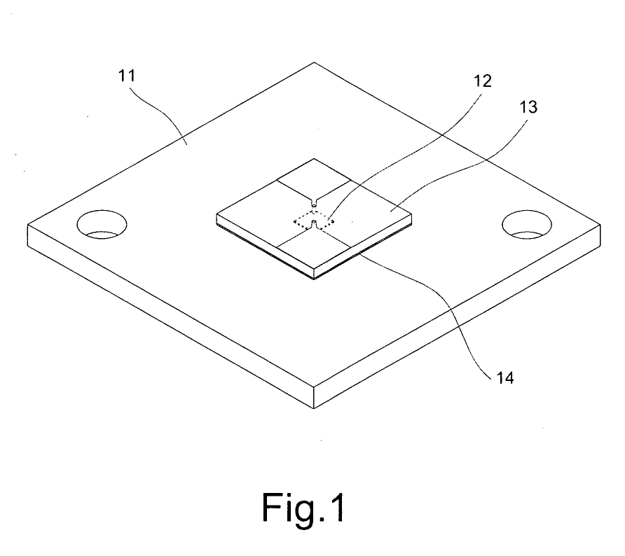

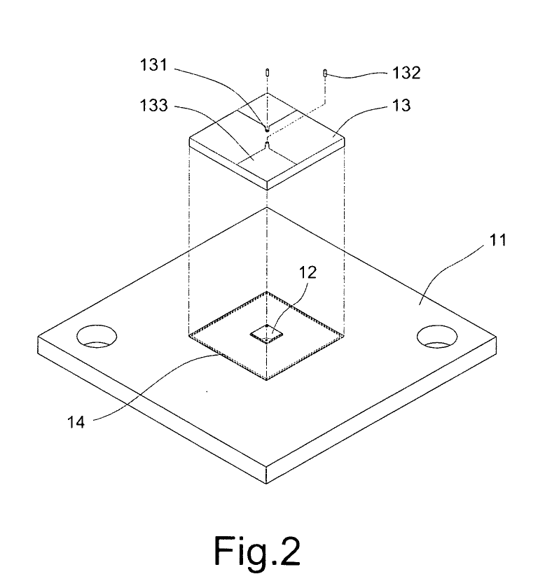

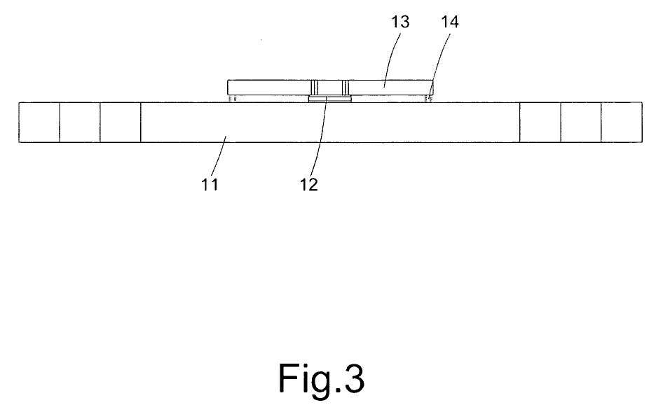

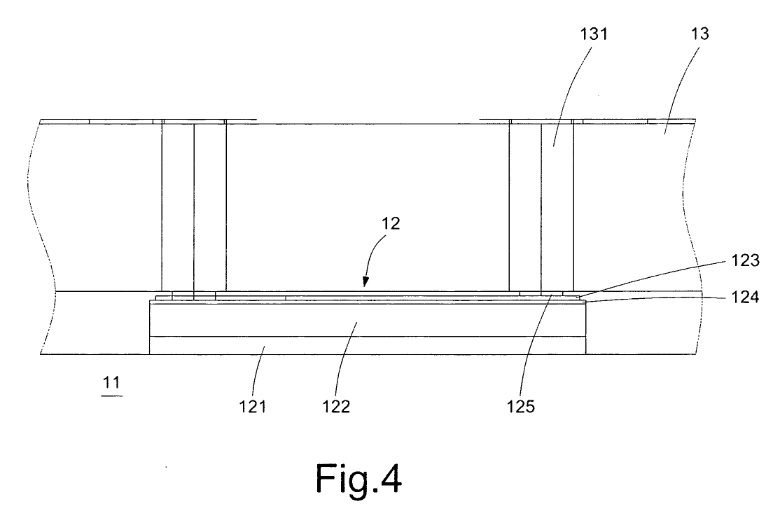

Referring to FIGS. 1, 2, 3, and 4, an LED packaging structure and a manufacturing method of the structure is comprised of a metal substrate 11, which is related to Al or other heat conductive material; a die 12 is fixed at where appropriately to the metal substrate 11; a transparent substrate 13 made of a vitreous material, a transparent substance or a transparency is overlapped on a top of the die 12; and at where between the metal substrate 11 and the transparent substrate 13, a seal 14 is used to pack where surrounding the die 12.

In the die 12, an underfill 121 is used to bond the LED substrate 122 and the metal substrate 11′ a P-electrode 123, an N-electrode 124, and a bond 125 are formed on the LED substrate 122, a through hole 131 is drilled over each bond 125 on the transparent substrate 13 disposed on top of the die 12. The through hole contains a conductive material 132 and a conductive layer is laminated on an inner wall of the through hole 131. The conductive material is printed or dispensed with a conductive epoxy, e.g., silver epoxy, solder paste, and solder ball, and printing or dispense of the conductive epoxy may be provided in a vacuum chamber to prevent residual air bulbs in the through hole.

A conductive layer needs to be deposed and patterned on the transparent substrate 13, and the conductive layer may be provided using metal, e.g., Al, Cr, or IndiumTin Oxide (ITO). Whereas the ITO is related to a transparent material, it is capable of increasing aperture ratio and manufacturing of circuit for the LED.

A contact circuit 133 is disposed by the through hole 131 over, below, or over and below the transparent substrate 13.

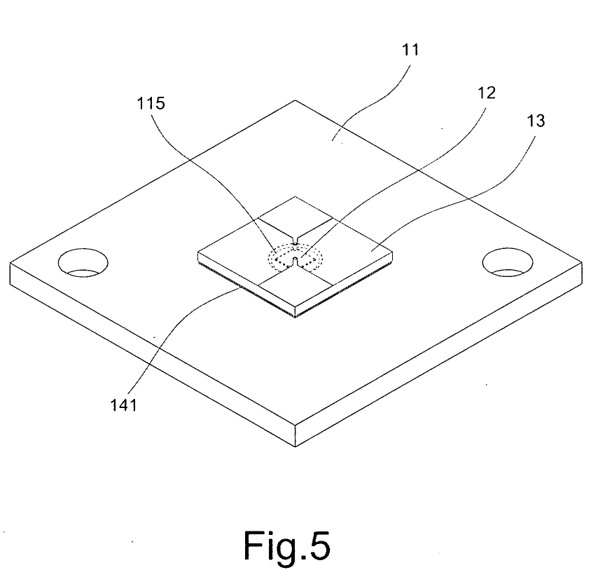

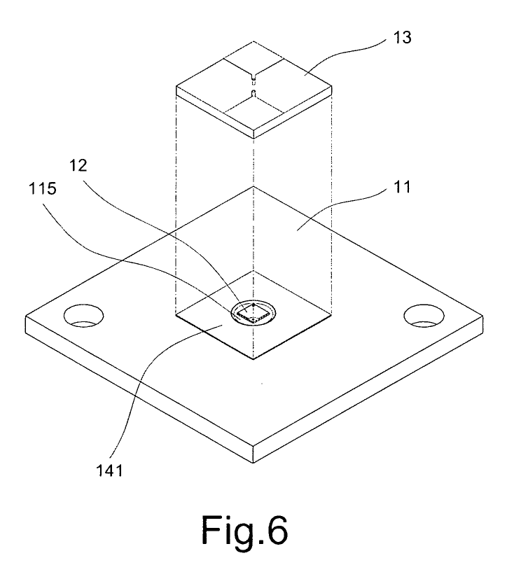

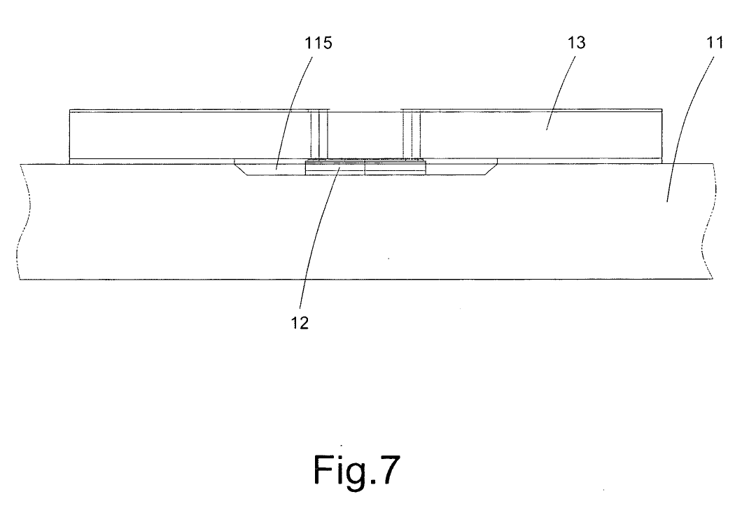

The metal substrate 11 in the first preferred embodiment is related to a flat one, and the metal substrate 11 of a second preferred embodiment of the present invention as illustrated in FIGS. 5, 6, and 7 has a dent at its center, i.e., a trough 115 is formed at where the die 12 is placed to realize a special combination method by insertion. A seal 141 is fully coated on all contact surfaces found between the metal substrate 11 and the transparent substrate 13 to allow the present invention particularly suitable for mass production by lot or for packaging production of LED trim.

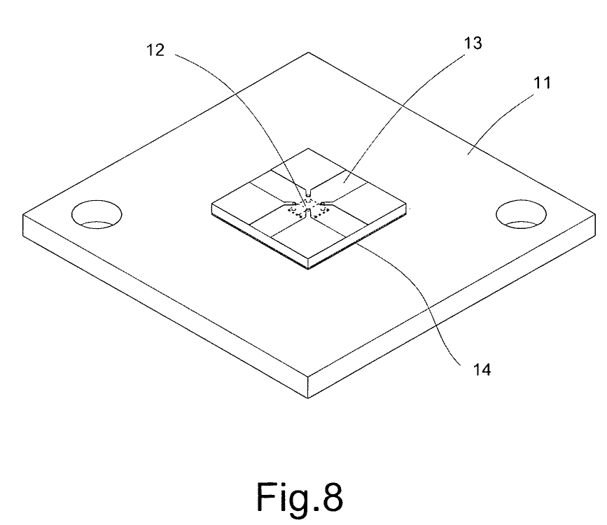

FIG. 8 shows a schematic view of a structure of having RGB multi-chip packaging in assorted colors for the LED of the present invention.

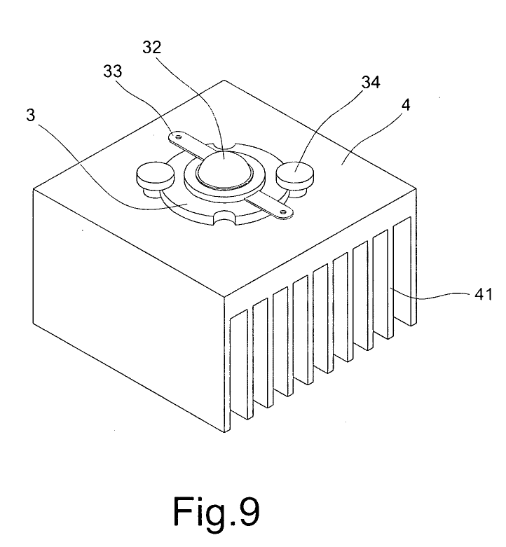

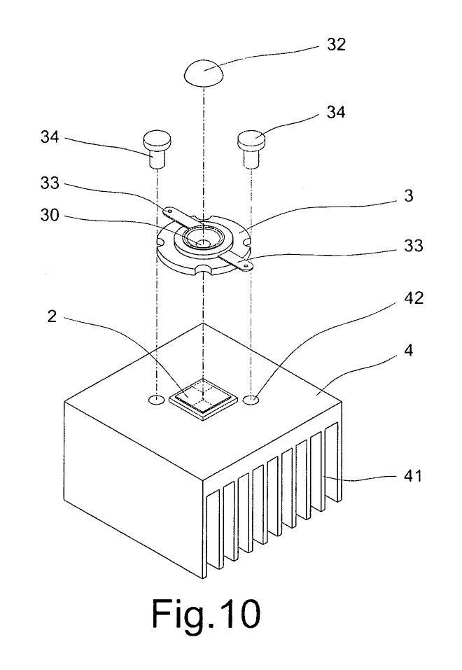

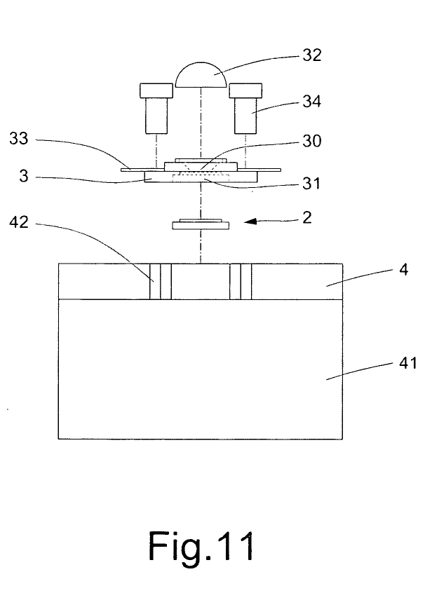

As illustrated in FIGS. 9, 10, and 11, an LED packaging structure 2 is combined to a heat sink 4 through a connection unit 3. The heat sink 4 includes multiple fins 41 and multiple locking holes 42 are disposed at where appropriately on the heat sink 4. An accommodation trough 31 is formed in a bottom of the connection unit 3 to receive the LED packaging structure in position. A through hole 30 is disposed at a center of the connection unit 3 to allow irradiation from a light source of the LED packaging structure 2; the through hole 30 is covered up with a lens 32; multiple conductive plates 33 are disposed to the combination unit 3 to electrically connect to a wiring of the LED packaging structure 2; and the connection unit 3 is locked in those locking holes 42 on the heat sink 4 with corresponding fasteners 34.

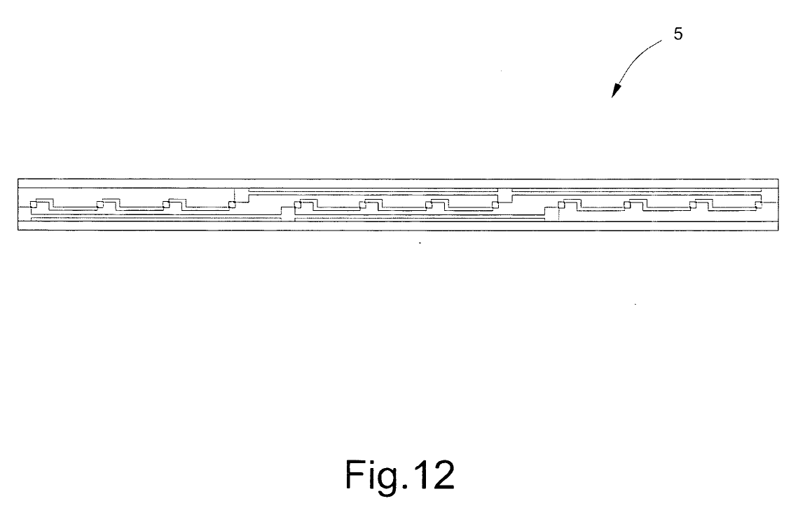

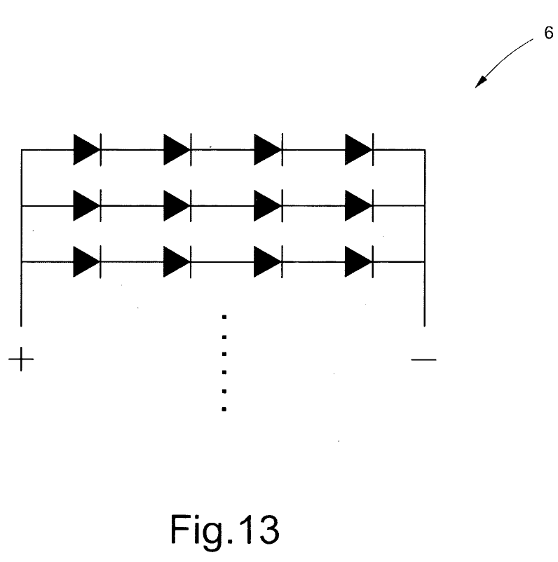

As illustrated in FIG. 12, the present invention is made into an LED light bar 5 as applicable, and wiring among multiple LEDs may be directly connected, i.e., an equivalent circuit 6 as illustrated in FIG. 13.

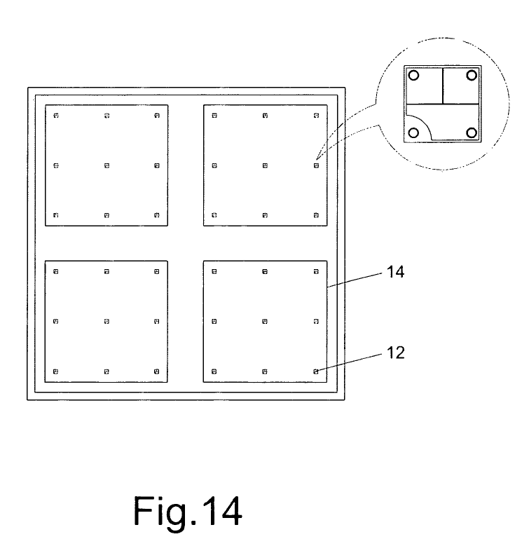

The LED packaging structure of the present invention may be provided as a single package as described in the first and the second preferred embodiments above, or in a local area package as illustrated in FIG. 14. Within the same seal 14, multiple dies are provided to permit larger area of multiple units to be bonded first before cutting into multiple breaks to meet mass production by lot.

1. An LED packaging structure comprising:
a metal substrate;
a die fixed on the metal substrate;
a transparent substrate overlapped on a top of the die; and
a seal used to package surrounding the die between the metal substrate and the transparent substrate.

2. The LED packaging structure as claimed in claim 1, wherein an underfill combines the LED substrate and an aluminum plate in the die, and a P-electrode and an N-electrode are provided thereon to form contacts.

3. The LED packaging structure as claimed in claim 1, wherein the transparent substrate includes a vitreous material, a transparent substance or a transparency; one through hole is disposed on the transparent substrate; and the metal substrate is made of aluminum.

4. The LED packaging structure as claimed in claim 3, wherein the through hole is provided in relation to the contact of the die; the through hole contains a conductive material; a conductive layer is laminated on an inner wall of the through hole; the conductive material is printed or dispensed with a conductive epoxy of silver epoxy, solder paste, and solder ball; and printing or dispense of the conductive epoxy is provided in a vacuum chamber to prevent residual air bulbs in the through hole.

5. The LED packaging structure as claimed in claim 1, wherein a conductive layer laminated on the transparent substrate is processed using metal, or IndiumTin Oxide (ITO); wiring is disposed at where appropriately by the through hole over the transparent substrate; wiring of the transparent substrate is disposed on either and/or both sides of the transparent substrate, and a protection layer including epoxy or insulator masks the wiring other than the contact.

6. The LED packaging structure as claimed in claim 1, wherein the metal substrate has a dent at center thereof to form a trough for receiving placement of the die; and a seal is fully or partially coated between the metal substrate and the transparent substrate.

7. The LED packaging structure as claimed in claim 1, wherein the die is RGB multi-chip packed in assorted colors.

8. The LED packaging structure as claimed in claim 1, wherein one or a plurality of die is contained in the same seal.

9. The LED packaging structure as claimed in claim 1, wherein the LED is made into an LED light bar.

10. The LED packaging structure as claimed in claim 1, wherein the LED packaging structure is combined to a heat sink through a connection unit; the heat sink includes multiple fins; multiple locking holes are disposed on the heat sink; an accommodation trough is formed in a bottom of the connection unit to receive the LED packaging structure in position; a through hole is disposed at a center of the connection unit to allow irradiation from a light source of the LED packaging structure; the through hole is covered up with a lens; multiple conductive plates are disposed to the combination unit to electrically connect to a wiring of the LED packaging structure; and the connection unit is locked in those locking holes on the heat sink with corresponding fasteners.

11. An LED packaging structure manufacturing method comprising:
preparing a metal substrate;
having a die bonded to the metal substrate; and
having a transparent substrate to overlap on a top of the die and proceed packaging with seal surrounding the die between the metal substrate and the transparent substrate.

12. The LED packaging structure manufacturing method as claimed in claim 11, wherein an underfill combines the LED substrate and an aluminum plate in the die, and a P-electrode and an N-electrode are provided thereon to form contacts.

13. The LED packaging structure manufacturing method as claimed in claim 11, wherein the transparent substrate includes a vitreous material, a transparent substance or a transparency; one through hole is disposed on the transparent substrate; and the metal substrate is made of aluminum.

14. The LED packaging structure manufacturing method as claimed in claim 13, wherein the through hole is provided in relation to the contact of the die; the through hole contains a conductive material; a conductive layer is laminated on an inner wall of the through hole; the conductive material is printed or dispensed with a conductive epoxy of silver epoxy, solder paste, and solder ball; and printing or dispense of the conductive epoxy is provided in a vacuum chamber to prevent residual air bulbs in the through hole.

15. The LED packaging structure manufacturing method as claimed in claim 11, wherein a conductive layer laminated on the transparent substrate is processed using metal, or IndiumTin Oxide (ITO); wiring is disposed at where appropriately by the through hole over the transparent substrate; wiring of the transparent substrate is disposed on either and/or both sides of the transparent substrate, and a protection layer including epoxy or insulator masks the wiring other than the contact.

16. The LED packaging structure manufacturing method as claimed in claim 11, wherein the metal substrate has a dent at center thereof to form a trough for receiving placement of the die; and a seal is fully or partially coated between the metal substrate and the transparent substrate.

17. The LED packaging structure manufacturing method as claimed in claim 11, wherein the die is RGB multi-chip packed in assorted colors.

18. The LED packaging structure as claimed in claim 11, wherein one or a plurality of die is contained in the same seal.

19. The LED packaging structure manufacturing method as claimed in claim 11, wherein the LED is made into an LED light bar.

20. The LED packaging structure manufacturing method as claimed in claim 11, wherein the LED packaging structure is combined to a heat sink through a connection unit; the heat sink includes multiple fins; multiple locking holes are disposed at where appropriately on the heat sink; an accommodation trough is formed in a bottom of the connection unit to receive the LED packaging structure in position; a through hole is disposed at a center of the connection unit to allow irradiation from a light source of the LED packaging structure; the through hole is covered up with a lens; multiple conductive plates are disposed to the combination unit to electrically connect to a wiring of the LED packaging structure; and the connection unit is locked in those locking holes on the heat sink with corresponding fasteners.
